(19) United States
(12) Patent Application Publication
(10) Pub. No.: US 2013/0111746 A1
(43) Pub. Date: May 9, 2013

(54) METHOD OF MANUFACTURING MULTILAYER WIRING SUBSTRATE

(71) Applicant: NGK Spark Plug Co., LTD., Nagoya-shi (JP)

(72) Inventors: Shinnosuke MAEDA, Nagoya-shi (JP); Tetsuo SUZUKI, Takahama-shi (JP); Takuya HANDO, Inuyama-shi (JP); Atsuhiko SUGIMOTO, Kagamigahara-shi (JP); Satoshi HIRANO, Chita-gun (JP); Hajime SAIKI, Cupertino, CA (US)

(73) Assignee: NGK SPARK PLUG CO., LTD., Nagoya-shi (JP)

(21) Appl. No.: 13/670,629

(22) Filed: Nov. 7, 2012

(30) Foreign Application Priority Data
Nov. 9, 2011 (JP) 2011-245558
Sep. 10, 2012 (JP) 2012-198437

(51) Int. Cl. H05K 3/10

(52) U.S. Cl. 29/846

(57) ABSTRACT

A method of manufacturing a multilayer wiring substrate includes: a first laminate structure formation step of forming a first laminate structure on a support substrate, the first laminate structure including at least one conductor layer and at least one resin insulation layer; a core substrate formation step of laminating a core substrate on the first laminate structure such that a lower main surface of the core substrate comes in contact with the first laminate structure, the core substrate having a metal layer provided on an upper main surface thereof; and a second laminate structure formation step of forming a second laminate structure on the core substrate such that the second laminate structure covers the metal layer, the second laminate structure including at least one conductor layer and at least one resin insulation layer.

### CROSS REFERENCE TO RELATED APPLICATION

The present application claims priority from Japanese Patent Application No. 2011-245558, which was filed on Nov. 9, 2011, and Japanese Patent Application No. 2012-198437, which was filed Sep. 10, 2012, the disclosures of which are hereby incorporated by reference in their entirety.

### BACKGROUND OF THE INVENTION

1. Field of the Invention

The present invention relates to a method of manufacturing a multilayer wiring substrate.

2. Description of Related Art

Generally, as a package on which an electronic part is mounted, a multilayer wiring substrate in which resin insulation layers and electric conductor layers are alternately laminated to form a build-up layer on each of opposite sides of a core substrate is used (Patent Document 1). In such a multilayer wiring substrate, the core substrate is formed of, for example, a resin including glass fibers, and reinforces the build-up layer by its high rigidity. However, the core substrate is thickly formed, which hinders the miniaturization of the multilayer wiring substrate. Accordingly, in recent years, the core substrate has been thinned so as to reduce the size of the multilayer wiring substrate.

However, thinning of the core substrate has raised a problem. Namely, thinning of the core substrate decreases the strength of an assembly which is formed in a manufacturing process and which includes the core substrate (semi-manufactured substrate which is to become a multilayer wiring substrate). As a result, the core substrate or the assembly can not be horizontally transported, and the core substrate or the assembly comes in contact with transport equipment during transportation, whereby the core substrate or the assembly is damaged. In addition, there has been a problem that when the core substrate or the assembly is fixed and supplied to a predetermined manufacturing step, the core substrate or the assembly deforms, which makes it difficult to accurately carry out treatment such as plating treatment. As a result, such a multilayer wiring substrate including a core substrate has had a problem that when the thickness of the core substrate is decreased, the manufacturing yield thereof decreases.

From such point of view, there has been proposed a so-called coreless multilayer wiring substrate which includes no core substrate, which is suitable for miniaturization, and which has a structure enhancing the performance of transmitting high-frequency signals (Patent Documents 2 and 3). Such a coreless multilayer wiring substrate is manufactured, for example, through a process in which a build-up layer is formed on a support substrate having a release sheet provided thereon, which is a laminate of two separable metal films, followed by the separation of the build-up layer from the support substrate at the peeling or separation interface of the release sheet, so that an intended multilayer wiring substrate is obtained.

However, such a coreless multilayer wiring substrates has a problem that, since the coreless multilayer wiring substrates has no core layer, it is low in strength and requires careful handling, and its application is limited.

### RELATED ART DOCUMENTS

### Patent Documents

Patent Document 1 is Japanese Patent Application Laid-Open (kokai) No. H11-233937.
Patent Document 2 is Japanese Patent Application Laid-Open (kokai) No. 2009-289848.
Patent Document 3 is Japanese Patent Application Laid-Open (kokai) No. 2007-214427.

### BRIEF SUMMARY OF THE INVENTION

An object of the present invention is to provide a method of manufacturing a multilayer wiring substrate in which a laminate structure, including at least one conductor layer and at least one resin insulation layer that are alternately laminated, is provided on each of opposite sides of a core substrate. The method can decrease the thickness of the core substrate and miniaturize the multilayer wiring substrate without decreasing the manufacture yield.

In order to achieve the above object, the present invention provides a method of manufacturing a multilayer wiring substrate, comprising:

a first laminate structure formation step of forming a first laminate structure on a support substrate, the first laminate structure including at least one conductor layer and at least one resin insulation layer;

a core substrate formation step of laminating a core substrate on the first laminate structure such that a lower main surface of the core substrate comes in contact with the first laminate structure, the core substrate having a metal layer provided on an upper main surface thereof; and

a second laminate structure formation step of forming a second laminate structure on the core substrate, the second laminate structure including at least one conductor layer and at least one resin insulation layer.

According to the present invention, in a method of manufacturing a so-called coreless multilayer wiring substrate in which a laminate structure (first laminate structure) including at least one conductor layer and at least one resin insulation layer is formed on a support substrate, a core substrate is also laminated together with the laminate structure, and an additional laminate structure having a configuration similar to that of the first laminate structure is laminated on the core substrate. In the method of manufacturing the coreless multilayer wiring substrate, the support substrate is removed after formation of the laminate structure on the support substrate as mentioned above. Therefore, final structure comprises the core substrate sandwiched between the laminate structures, each including at least one conductor layer and at least one resin insulation layer; namely, a multilayer wiring substrate having a core substrate.

In the present invention, as described above, a method of manufacturing a coreless multilayer wiring substrate is utilized for manufacture of a multilayer wiring substrate having a core substrate whose thickness is 200 μm or less. Therefore, the laminate structure and the core substrate are formed on the support substrate during the process of manufacturing the multilayer wiring substrate. Accordingly, even when the core substrate has a reduced thickness, the strength of an assembly formed in the manufacturing process is prevented from lowering by increasing the thickness of the support substrate to a sufficient degree.

Accordingly, the assembly formed in the manufacturing process can be horizontally transported, and it becomes possible to avoid the occurrence of a problem that the assembly comes in contact with transport equipment during transportation, whereby the core substrate or the assembly is damaged. Also, it becomes possible to avoid the occurrence of a problem that, when the assembly is fixed and supplied to a predetermined manufacturing step, the assembly deforms, so that it becomes difficult to accurately carry out treatment such as plating treatment. For this reason, the multilayer wiring substrate including a thin core substrate can be obtained with a high manufacturing yield, and thus the multilayer wiring substrate having the core substrate can be miniaturized.

The above-described method of the present invention is not limited to manufacture of a multilayer wiring substrate which includes a thin core substrate and which has such a structure that, if a common manufacturing method is used, due to the thin core substrate, the core substrate or an assembly formed in the manufacturing process deforms, which lowers manufacturing yield. The method of the present invention can be applied to the case where a multilayer wiring substrate includes a thick core substrate, and, even if a common manufacturing method is used, the multilayer wiring substrate including the thick core substrate can be manufactured with a high manufacturing yield.

In one mode of the present invention, the core substrate formation step may include forming a through hole in the core substrate laminated on the first laminate structure, and filling the through hole with plating. In this case, the plating metal filling the through hole functions as an interlayer connection body (via) for electrically connecting the laminate structures formed on the opposite sides of the core substrate. Therefore, as the length of wiring for electrically connecting these laminate structures decreases, the occurrence of problems such as deterioration in the performance of transmitting high-frequency signals is prevented.

In a conventional method of manufacturing a multilayer wiring substrate having a core substrate, the through hole conductors must be provided in the core substrate so as to electrically connect the laminate structures formed on the opposite sides of the core substrate. For this reason, as the length of wiring for electrically connecting the laminate structures inevitably increases, the high-frequency signal transmission performance may deteriorate.

In one mode of the present invention, the core substrate formation step may include forming a through hole in the core substrate laminated on the first laminate structure, forming a plating layer on the wall surface of the through hole, and forming with a resin insulating material the resin insulation layer of the second laminate structure and an insulator which fills the through hole. In this case, it is possible to eliminate complicated steps in a conventional method of manufacturing a multilayer wiring substrate having a core substrate, such as a step of plating through holes of the core substrate, a step of burying the through hole by filling the through hole with resin, and a step of polishing the filling resin. That is, the manufacturing steps of the multilayer wiring substrate including a core substrate can be simplified.

In one mode of the present invention, the core substrate formation step may include removing the metal layer at a location where the through hole is to be formed in the core substrate; and the through hole may be formed through irradiation of laser light. In this case, the metal layer is not present at a position where the through hole is to be formed. Therefore, in the case where the through hole is formed by irradiation of laser light, the irradiation energy can be decreased, whereby the manufacturing cost of the multilayer wiring substrate with a core substrate can be decreased.

In one mode of the present invention, the core substrate formation step may include laminating the core substrate on the first laminate structure by pressure-bonding the core substrate to the first laminate structure at a temperature equal to or higher than the glass transition point of the resin insulation layer of the first laminate structure. In this case, when the core substrate is formed on the first laminate structure, warpage of the first laminate structure can be reduced, and warpage of at least a portion of the multilayer wiring substrate including a core substrate, which portion is located below the core substrate, can be reduced. Accordingly, warpage of the entire multilayer wiring substrate can be reduced.

As explained hereinbefore, according to the present invention, there can be provided a method of manufacturing a multilayer wiring substrate in which a laminate structure including alternately laminated at least one conductor layer and at least one resin insulation layer is provided on each of opposite sides of a core substrate. The method can decrease the thickness of the core substrate and miniaturize the multilayer wiring substrate without decreasing the manufacture yield.

### BRIEF DESCRIPTION OF THE DRAWINGS

Illustrative aspects of the invention will be described in detail with reference to the following figures wherein:

FIG. 1 is a plan view of a multilayer wiring substrate according to a first embodiment.

FIG. 2 is a plan view of the multilayer wiring substrate according to the first embodiment.

FIG. 3 is an enlarged partial sectional view of the multilayer wiring substrate shown in FIGS. 1 and 2 which is taken along line “I-I”.

FIG. 4 is a sectional view showing a step of a method of manufacturing the multilayer wiring substrate according to the first embodiment.

FIG. 5 is a sectional view showing another step of the method of manufacturing the multilayer wiring substrate according to the first embodiment.

FIG. 6 is a sectional view showing another step of the method of manufacturing the multilayer wiring substrate according to the first embodiment.

FIG. 7 is a sectional view showing another step of the method of manufacturing the multilayer wiring substrate according to the first embodiment.

FIG. 8 is a sectional view showing another step of the method of manufacturing the multilayer wiring substrate according to the first embodiment.

FIG. 9 is a sectional view showing another step of the method of manufacturing the multilayer wiring substrate according to the first embodiment.

FIG. 10 is a sectional view showing another step of the method of manufacturing the multilayer wiring substrate according to the first embodiment.

FIG. 11 is a sectional view showing another step of the method of manufacturing the multilayer wiring substrate according to the first embodiment.

FIG. 12 is a sectional view showing another step of the method of manufacturing the multilayer wiring substrate according to the first embodiment.

FIG. 13 is a sectional view showing another step of the method of manufacturing the multilayer wiring substrate according to the first embodiment.

FIG. 14 is a sectional view showing another step of the method of manufacturing the multilayer wiring substrate according to the first embodiment.

FIG. 15 is a sectional view showing another step of the method of manufacturing the multilayer wiring substrate according to the first embodiment.

FIG. 16 is a sectional view showing another step of the method of manufacturing the multilayer wiring substrate according to the first embodiment.

FIG. 17 is an enlarged partial sectional view of a multilayer wiring substrate according to a second embodiment.

FIG. 18 is a sectional view showing a step of a method of manufacturing the multilayer wiring substrate according to the second embodiment.

FIG. 19 is a sectional view showing another step of the method of manufacturing the multilayer wiring substrate according to the second embodiment.

FIG. 20 is a sectional view showing another step of the method of manufacturing the multilayer wiring substrate according to the second embodiment.

FIG. 21 is a sectional view showing another step of the method of manufacturing the multilayer wiring substrate according to the second embodiment.

### DETAILED DESCRIPTION OF EXEMPLARY EMBODIMENTS OF THE INVENTION

Preferred embodiments of the present invention will next be described with reference to the drawings.

### First Embodiment

Multilayer Wiring Substrate

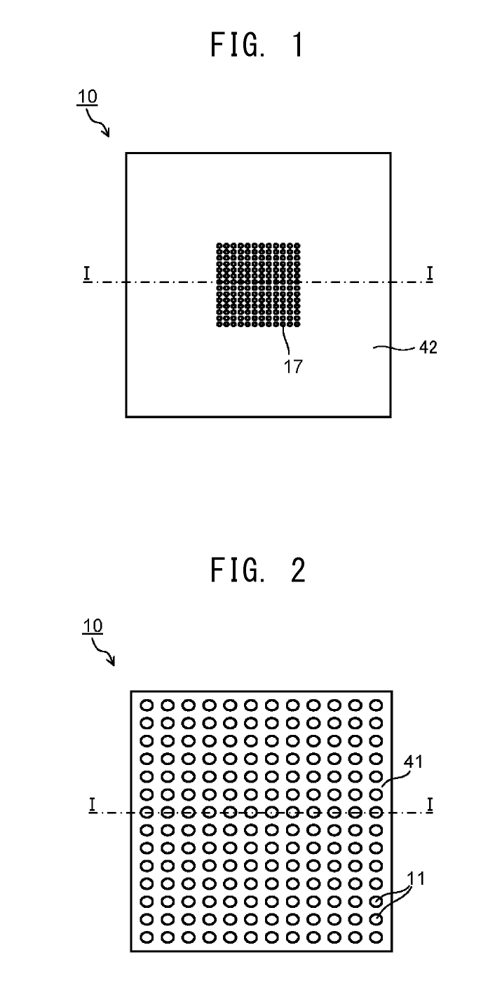

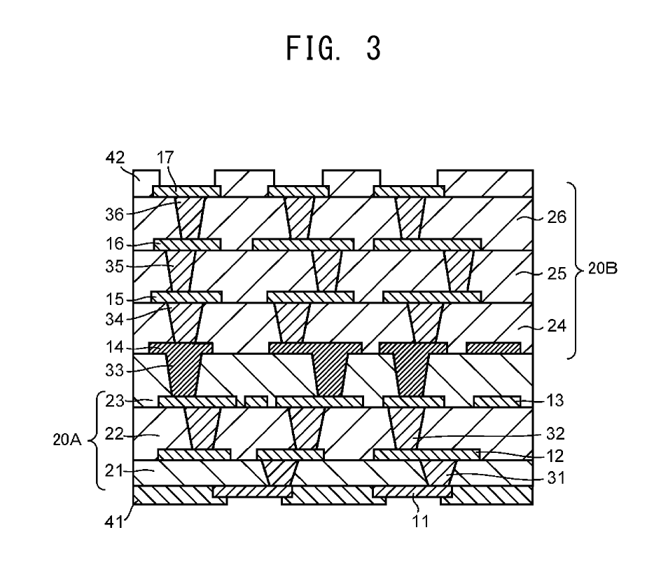

First, an example of a multilayer wiring substrate manufactured using a method of the present invention will be explained. FIGS. 1 and 2 are plan views showing a multilayer wiring substrate according to the present embodiment. FIG. 1 is a view of the multilayer wiring substrate as viewed from the upper side. FIG. 2 is a view of the multilayer wiring substrate as viewed from the lower side. FIG. 3 is an enlarged partial sectional view of the multilayer wiring substrate shown in FIGS. 1 and 2 which is taken along line I-I.

A multilayer wiring substrate described below is a mere illustrative example which clarifies the feature of the present invention, and the present invention is not limited thereto, provided that the multilayer wiring substrate has a structure in which a core substrate is sandwiched between first and second laminate structures each including at least one conductor layer and at least one resin insulation layer that are alternately laminated.

The multilayer wiring substrate 10 shown FIGS. 1 to 3 includes first to seventh conductor layers 11 to 17 and first to sixth resin insulation layers 21 to 26, which are laminated alternately.

Specifically, the first resin insulation layer 21 is laminated on the first conductor layer 11, the second conductor layer 12 is laminated on the first resin insulation layer 21, the second resin insulation layer 22 is laminated on the second conductor layer 12, and the third conductor layer 13 is laminated on the second resin insulation layer 22. Further, the third resin insulation layer 23 is laminated on the third conductor layer 13, the fourth conductor layer 14 is laminated on the third resin insulation layer 23, the fourth resin insulation layer 24 is laminated on the fourth conductor layer 14, and the fifth conductor layer 15 is laminated on the fourth resin insulation layer 24. In addition, the fifth resin insulation layer 25 is laminated on the fifth conductor layer 15, the sixth conductor layer 16 is laminated on the fifth resin insulation layer 25, the sixth resin insulation layer 26 is laminated on the sixth conductor layer 16, and the seventh conductor layer 17 is laminated on the sixth resin insulation layer 26.

Each of the first to seventh conductor layers 11 to 17 is formed of a material having excellent electrical conductivity, such as copper. Each of the first resin insulation layer 21, the second resin insulation layer 22, and the fourth to sixth resin insulation layers 24 to 26 is formed of a thermosetting resin composition including a silica filler or the like if necessary. The third resin insulation layer 23 is a sheet-like core substrate formed from a plate of heat-resistant resin (such as bismaleimide-triazine resin), a plate of fiber reinforced resin (such as glass fiber-reinforced epoxy resin), or the like.

A first resist layer 41 is formed on the first conductor layer 11 such that the first conductor layer 11 is partially exposed. A second resist layer 42 is formed on the seventh conductor layer 17 such that the seventh conductor layer 17 is partially exposed.

The portions of the first conductor layer 11 exposed from the first resist layer 41 serve as back side lands (LGA pads) for connecting the multilayer wiring substrate 10 to a mother board, and are arrayed in a rectangular area on the back side of the multilayer wiring substrate 10. The portions of the seventh conductor layer 17 exposed from the second resist layer 42 serve as pads (FC pads) for connecting a semiconductor device or the like (not shown) to the multilayer wiring substrate 10. The portions serving as FC pads are arrayed in a rectangular area at the approximate center of the surface of the multilayer wiring substrate 10, the rectangular area serving as a semiconductor device mounting area.

First via conductors 31 are formed in the first resin insulation layer 21, and the first conductor layer 11 and the second conductor layer 12 are electrically connected to each other via the first via conductors 31. Second via conductors 32 are formed in the second resin insulation layer 22, and the second conductor layer 12 and the third conductor layer 13 are electrically connected to each other via the second via conductors 32. Third via conductors 33 are formed in the third resin insulation layer 23, and the third conductor layer 13 and the fourth conductor layer 14 are electrically connected to each other via the third via conductors 33. Fourth via conductors 34 are formed in the fourth resin insulation layer 24, and the fourth conductor layer 14 and the fifth conductor layer 15 are electrically connected to each other via the fourth via conductors 34. Fifth via conductors 35 are formed in the fifth resin insulation layer 25, and the fifth conductor layer 15 and the sixth conductor layer 16 are electrically connected to each other via the fifth via conductors 35. Sixth via conductors 36 are formed in the sixth resin insulation layer 26, and the sixth conductor layer 16 and the seventh conductor layer 17 are electrically connected to each other via the sixth via conductors 36.

In the present embodiment, the first conductor layer 11 to the third conductor layer 13, the first resin insulation layer 21 and the second resin insulation layer 22, and the first via conductors 31 and the second via conductors 32 constitute a first laminate structure 20A, while the fourth conductor layer 14 to the seventh conductor layer 17, the fourth resin insulation layer 24 to the sixth resin insulation layer 26, and the fourth via conductors 34 to the sixth via conductors 36 constitute a second laminate structure 20B.

Although no reference numeral is provided, respective portions of the first conductor layer 11 to the seventh conductor layer 17 which are connected to the first via conductors 31 to the sixth via conductors 36 constitute via lands (i.e. via pads), while respective portions of the first conductor layer 11 to the seventh conductor layer 17 which are not connected to the first via conductors 31 to the sixth via conductors 36 constitute wiring layers.

The multilayer wiring substrate 10 may have a size of 200 mmX 200 mmX 0.4 mm, for example.

Method of Manufacturing Multilayer Wiring Substrate

Next, a method of manufacturing the multilayer wiring substrate 10 shown in FIGS. 1 to 3 will be explained.

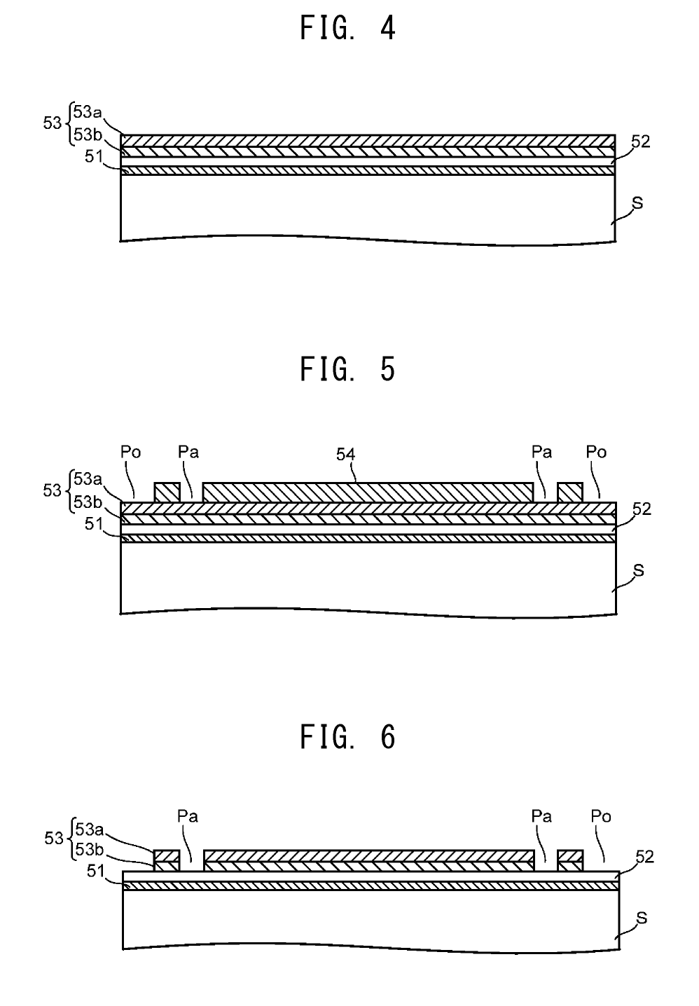

FIGS. 4 to 16 are views showing the steps of the method of manufacturing the multilayer wiring substrate 10 according to the present embodiment. Each of the views shown in FIGS. 4 to 16 corresponds to the cross-sectional view of the multilayer wiring substrate 10 shown in FIG. 3.

In actuality, the manufacturing method of the present invention is used to form the multilayer wiring substrate 10 on each of the opposite sides of a support substrate; however, in the present embodiment, a case where the multilayer wiring substrate 10 is formed only on one side of the support substrate will be described so as to clarify the features of the manufacturing method of the present invention.

First of all, as shown in FIG. 4, there is prepared a support substrate S having copper foils 51 bonded to opposite sides thereof. The support substrate S may be formed from a plate of heat resisting resin (such as bismaleimide-triazine resin), a plate of fiber reinforced resin (such as a glass fiber-reinforced epoxy resin), or the like. As will be described in detail later, in order to suppress the deformation of an assembly formed in the manufacturing process, the thickness of the support substrate S may be determined to fall within the range of 0.4 mm to 1.0 mm. Subsequently, by means of, for example, vacuum hot pressing, a release sheet 53 is press-bonded to the copper foil 51 on each of the opposite sides of the support substrate S via a prepreg layer 52 serving as a bonding layer.

The release sheet 53 is composed of, for example, a first metal film 53a and a second metal film 53b, and a layer of chromium is provided between these films through plating or the like such that these films can be separated from each other through application of an external tensile force thereto. Each of the first metal film 53a and the second metal film 53b may be formed of copper foil.

Next, as shown in FIG. 5, on each of the release sheets 53 formed on the opposite sides of the support substrate S, a photosensitive dry film is laminated, followed by the formation of a mask 54 through light exposure and development. The mask 54 has openings which correspond to an alignment mark formation portion Pa and a periphery defining portion Po.

Next, as shown in FIG. 6, on the support substrate S, etching treatment is applied to the release sheet 53 through the mask 54 so as to form the alignment mark formation portion Pa and the periphery defining portion Po in the release sheet 53 at positions corresponding to the above-mentioned openings. Notably, after formation of the alignment mark formation portion Pa and the periphery defining portion Po, the mask 54 is removed through etching.

It is preferred that etching treatment is applied to the surface of the release sheet 53, exposed as a result of the removal of the mask 54, so as to roughen the surface. Thus, the adhesion between the release sheet 53 and a resin insulation layer, which will be described later, can be enhanced.

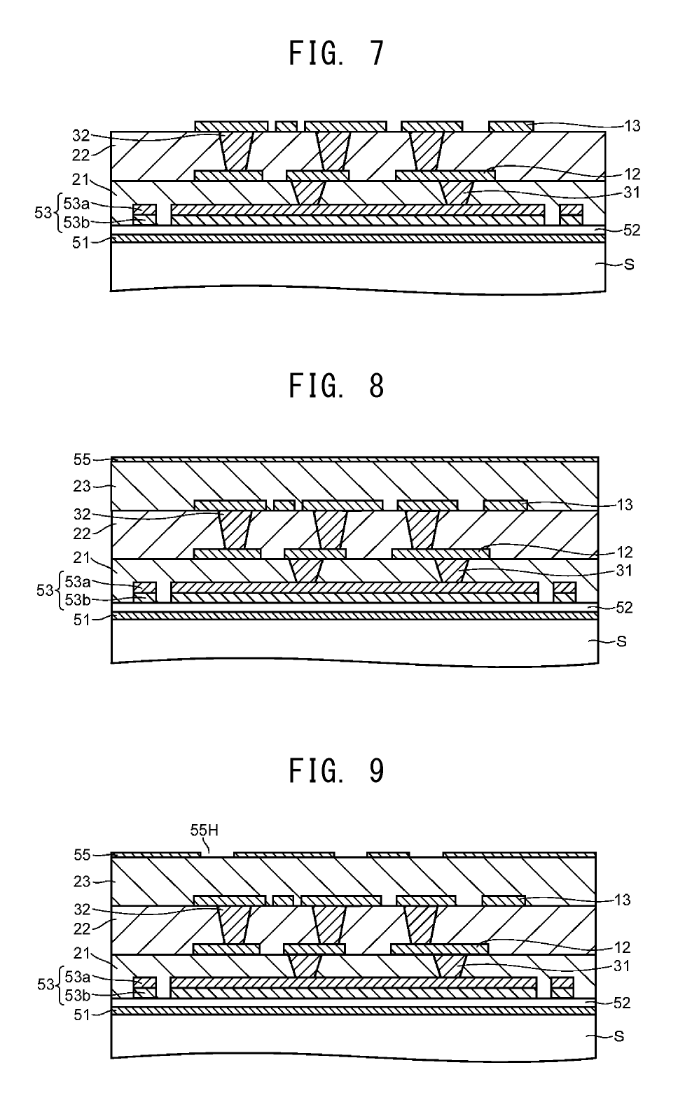

Next, as shown in FIG. 7, a resin film is laminated on the release sheet 53, followed by curing through application of pressure and heat thereto under vacuum, whereby the first resin insulation layer 21 is formed. As a result, the surface of the release sheet 53 is covered with the first resin insulation layer 21. Also, the opening constituting the alignment mark formation portion Pa and the cutout constituting the periphery defining portion Po are filled with the first resin insulation layer 21. Thus, a structure serving as an alignment mark is formed at the position of the alignment mark formation portion Pa.

Since the periphery defining portion Po is also covered with the first resin insulation layer 21, it is possible to eliminate a disadvantage that, in a release step which will be described later and which utilizes the release sheet 53, the end of the release sheet 53 separates and lifts, for example, from the prepreg layer 52, and thus the release step can not be carried out well, so that the multilayer wiring substrate 10 can not be manufactured as intended.

Subsequently, the first resin insulation layer 21 is irradiated with laser light having a predetermined intensity from a CO₂ gas laser or a YAG laser so as to form via holes in the first resin insulation layer 21. Desmearing and outline etching are then properly performed for the via holes, followed by surface roughening treatment for the first resin insulation layer 21 including the via holes.

In the case where the first resin insulation layer 21 includes a filler, the surface roughening treatment liberates the filler, and the filler remains on the first resin insulation layer 21. Therefore, water washing is properly carried out.

In addition, after the water washing, air blow may be carried out. Thus, even when the liberated filler has not been thoroughly removed through the water washing as mentioned above, the air blow can supplement the water washing for removing the filler.

Subsequently, pattern plating is applied to the first resin insulation layer 21 so as to form the second conductor layer 12 and the first via conductors 31. The second conductor layer 12 and the first via conductors 31 are formed as follows according to a semi-additive process. First of all, an electroless plating film is formed on the first resin insulation layer 21, and then a resist layer is formed on this electroless plating film. Copper electroplating is then performed on portions of the first resin insulation layer 21 where the resist layer is not formed, whereby the second conductor layer 12 and the first via conductors 31 are formed. After formation of the second conductor layer 12 and the first via conductor 31, the resist layer is separated and removed with potassium hydroxide or the like. The portions of the electroless plating film exposed as a result of removal of the resist layer are removed through etching.

Next, after the surface roughening treatment has been applied to the second conductor layer 12, a resin film is laminated on the first resin insulation layer 21 such that the second conductor layer 12 is covered, followed by application of pressure and heat thereto under vacuum so as to cure the same, whereby the second resin insulation layer 22 is formed. Subsequently, via holes are formed in the second resin insulation layer 22 in a similar way to the case of the first resin insulation layer 21, followed by pattern plating, whereby the third conductor layer 13 and the second via conductors 32 are formed. The specific conditions for forming the third conductor layer 13 and the second via conductors 32 are similar to those for forming the second conductor layer 12 and the first via conductors 31.

Through the steps shown in FIGS. 4 to 7, there is formed the first laminate structure 20A, which includes the first metal film 53a (which becomes the first conductor layer 11 later), the second and third conductor layers 12 and 13, the first and second resin insulation layers 21 and 22, and the first and second via conductors 31 and 32.

Then, as shown in FIG. 8, a prepreg layer 23X having a metal layer 55 formed on its upper main surface is laminated on the second resin insulation layer 22 such that the prepreg layer 23X covers the third conductor layer 13 and the lower main surface of the prepreg layer 23X comes in contact with the second resin insulation layer 22, followed by the hot pressing of the prepreg layer 23X under vacuum, whereby the prepreg layer 23X is pressure bonded to the second resin insulation layer 22 and is cured. Since the prepreg layer 23X includes reinforcing fibers such as fiberglass, the third resin insulation layer 23 is obtained by curing the prepreg layer 23X through application of heat thereto and constitutes a core substrate.

The above-mentioned vacuum hot pressing is carried out at a temperature equal to or higher than the glass transition point of the first resin insulation layer 21 and the second resin insulation layer 22 of the first laminate structure 20A. Therefore, when the core substrate comprising the metal layer 55 and the third resin insulation layer 23 is formed on the first laminate structure 20A, the first laminate structure 20A can be prevented from warping. As a result, it is possible to reduce warpage of at least a portion of the finally obtained multilayer wiring substrate 10, which portion is located below the third resin insulation layer (the core substrate) 23. Accordingly, warpage of the entire multilayer wiring substrate 10 can be reduced.

The third resin insulation layer 23 constituting the core substrate may have a thickness of 0.05 mm to 0.2 mm, and the metal layer 55 may have a thickness of 0.001 mm to 0.035 mm. The metal layer 55 may be formed of the same metal material as that of the first to seventh conductor layers 11 to 17; i.e., a material which is excellent in electrical conductivity such as copper.

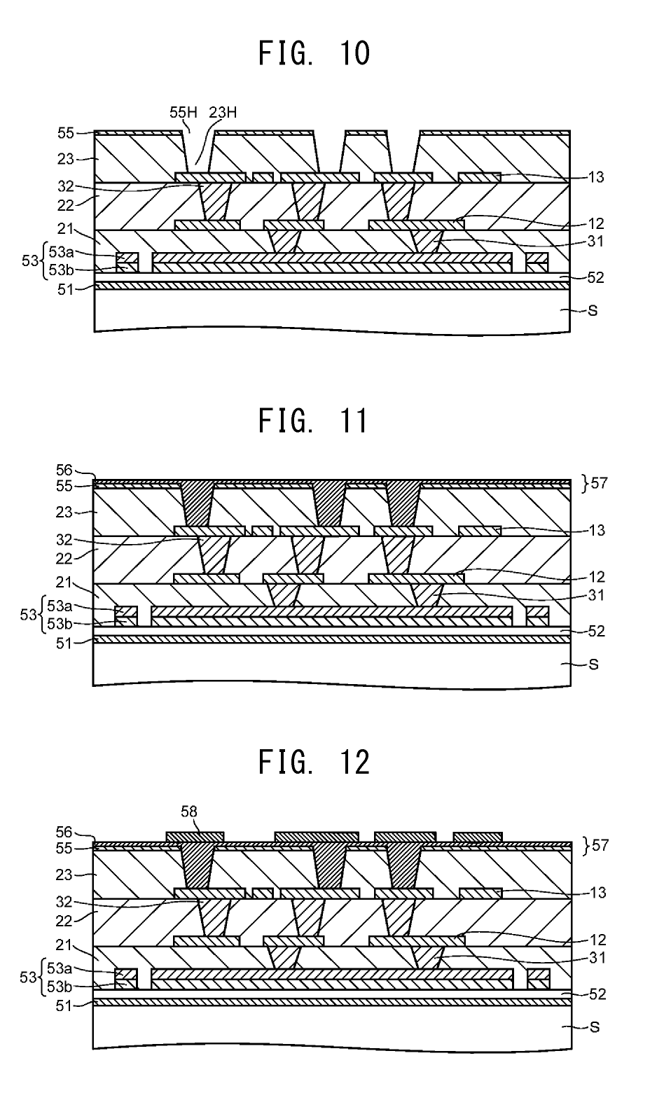

Next, as shown in FIG. 9, the metal layer 55 is partially etched and removed so as to form openings 55H, followed by irradiation of laser light to the third resin insulation layer 23 through the openings 55H so as to form through holes 23H as shown in FIG. 10 such that the third conductor layer 13 is exposed. In this case, in the step shown in FIG. 9, the openings 55H are previously formed in the metal layer 55 at positions where the through holes 23H are to be formed in the third resin insulation layer (the core substrate) 23. Therefore, the above-mentioned laser light impinges directly onto the third resin insulation layer 23 without passing through the metal layer 55.

Therefore, when the through holes 23H are formed using laser light in the third resin insulation layer 23 constituting the core substrate, a step of forming openings in the metal layer 55 using laser light can be omitted, and thus laser irradiation energy required for formation of the through holes 23H can be decreased, whereby the manufacturing cost of the multilayer wiring substrate 10 can be lowered.

In this regard, the step shown in FIG. 9 can be omitted. However, in this case, since the openings 55H must be formed in the metal layer 55 using laser light simultaneously with formation of the through holes 23H in the third resin insulation layer 23, the irradiation energy of laser light required for forming the through holes 23H increases. For this reason, the production cost of the multilayer wiring substrate 10 increases.

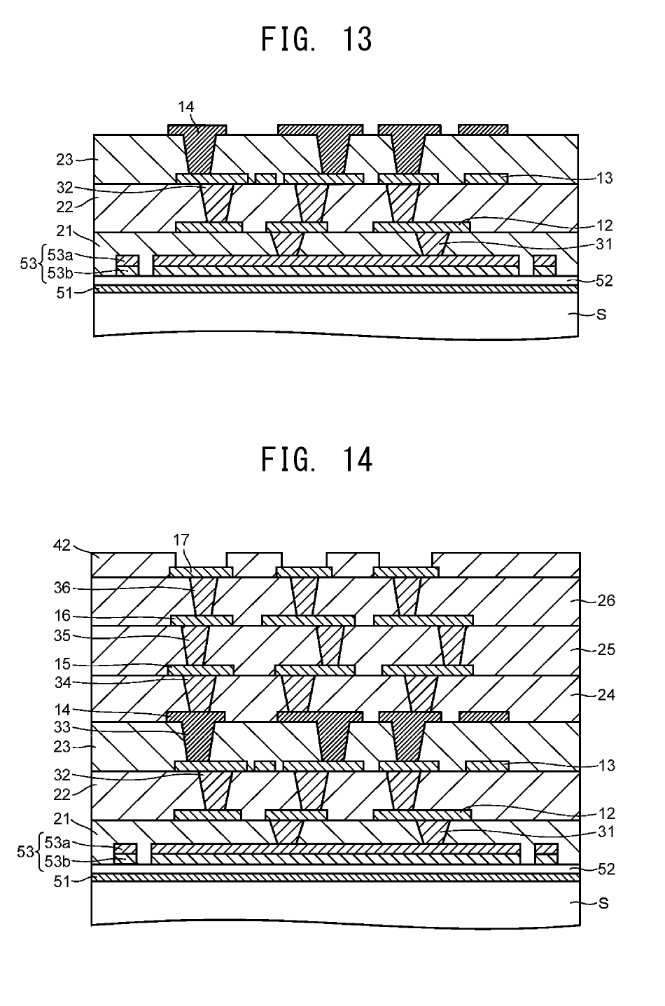

Then, desmearing and outline etching are properly applied to the through holes 23H, followed by electroless plating, whereby a plating ground layer (not shown) is formed on the wall surfaces of the through holes 23H. Thereafter, as shown in FIG. 11, a so-called filled via plating treatment is carried out so as to fill the through holes 23H with the plating material. In this case, the plating metal forms the third conductor vias 33 for electrically connecting the first laminate structure 20A and the second laminate structure 20B together, the first laminate structure 20A being formed on the lower side of the third resin insulation layer 23, and the second laminate structure 20B being formed on the upper side of the third resin insulation layer 23. Therefore, the length of wiring for electrically connecting these laminate structures decreases, which prevents occurrence of problems such as deterioration in the performance of transmitting high-frequency signals.

In a conventional method of manufacturing a multilayer wiring substrate having a core substrate, through hole conductors must be provided in the core substrate in order to electrically connect the laminate structures formed on the opposite sides of the core substrate. For this reason, the length of wiring for electrically connecting the laminate structures inevitably increases, which may deteriorate the high-frequency signal transmission performance.

Since a plating layer 56 is also formed on the metal layer 55 as a result of performance of the above-mentioned filled via plating, a metal laminate including the metal layer 55 and the plating layer 56 laminated thereon is represented by a reference numeral “57.” As mentioned above, the metal layer 55 can be formed of copper, and the plating layer 56 can be also formed of copper. Therefore, the plating layer 56 carries out the same function as the metal layer 55, and thus the metal laminate 57 can be a single metal layer.

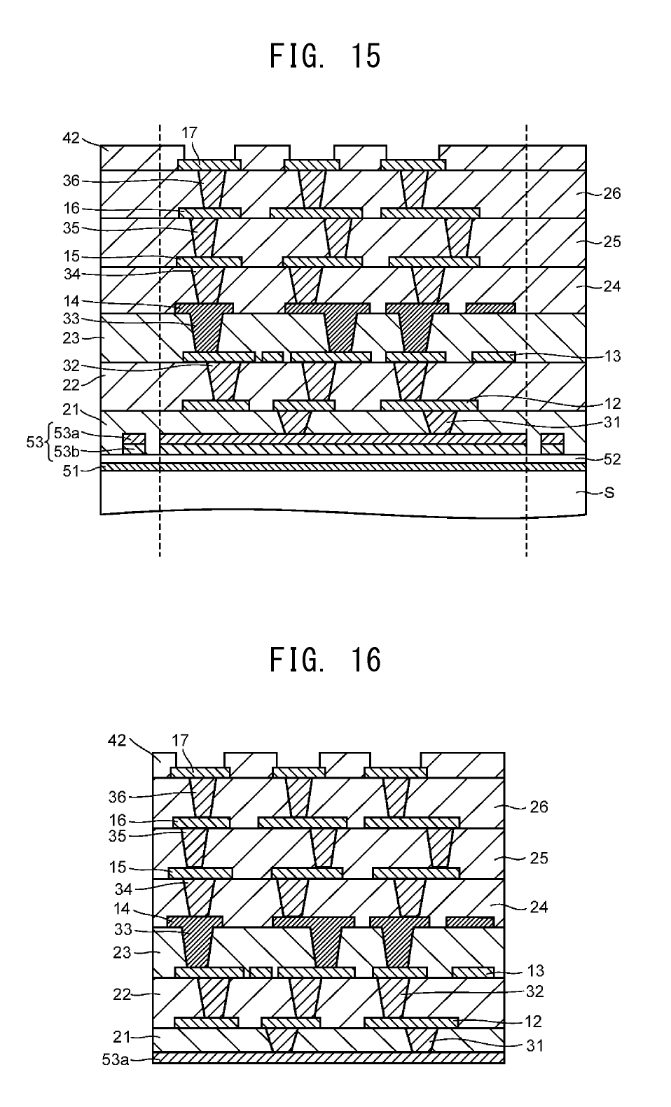

Subsequently, as shown in FIG. 12, a resist layer 58 of a predetermined pattern is formed on the metal laminate (the metal layer) 57, and then as shown in FIG. 13, the metal laminate (the metal layer) 57 is etched through openings of the resist layer 58, followed by the removal of the resist layer 58, whereby the fourth conductor layer 14 is formed on the third resin insulation layer 23.

In the case where copper foil is used for the metal layer 55, the fourth conductor layer 14 of the multilayer wiring substrate 10 shown in FIG. 3 is constituted by the metal laminate 57, that is, the metal layer 55 and the plating layer 56.

Next, after the fourth conductor layer 14 is roughened, as shown in FIG. 14, a resin film is laminated on the third resin insulation layer 23 such that the fourth conductor layer 14 is covered, followed by curing through application of pressure and heat to the resin film under vacuum, whereby the fourth resin insulation layer 24 is formed. Subsequently, in a similar way to the case of the first resin insulation layer 21, via holes are formed in the fourth resin insulation layer 24, followed by pattern plating, whereby the fifth conductor layer 15 and the fourth via conductors 34 are formed. The specific conditions for forming the fifth conductor layer 15 and the fourth via conductors 34 are similar to those for forming the second conductor layer 12 and the first via conductors 31.

As shown in FIG. 14, in a similar way to the fourth resin insulation layer 24, the fifth resin insulation layer 25 and the sixth resin insulation layer 26 are sequentially formed. Further, in a similar way to the fifth conductor layer 15 and the fourth via conductors 34, the sixth conductor layer 16 and the fifth via conductors 35 are formed on the fifth resin insulation layer 25, and the seventh conductor layer 17 and the sixth via conductors 36 are formed on the sixth resin insulation layer 26. Subsequently, the second resist layer 42 is formed such that the seventh conductor layer 17 is partially exposed.

The fourth to seventh conductor layers 14 to 17, the fourth to sixth resin insulation layers 24 to 26, and the fourth and fifth via conductors 34 and 35 constitute the second laminate structure 20B After that, as shown in FIG. 15, a laminate which is obtained through the above-described steps and which includes the first laminate structure 20A, the third resin insulation layer 23, and the second laminate structure 20B is cut along a cutting line set to be located slightly inward of the periphery defining portion Po so as to remove an unnecessary peripheral position of the laminate.

Then, as shown in FIG. 16, the multilayer wiring laminate obtained through the step as shown in FIG. 15 is divided at the release interface between the first metal film 53a and the second metal film 53b of the release sheet 53. Thus, the support substrate S is removed from the multilayer wiring laminate.

Subsequently, the first metal film 53a of the release sheet 53 left on the lower side of the multilayer wiring laminate obtained in the step of FIG. 16 is etched so as to form the first conductor layer 11. Thereafter, the first resist layer 41 is formed such that the first conductor layer 11 is partially exposed, whereby the multilayer wiring substrate 10 as shown in FIG. 3 is obtained.

The multilayer wiring substrate 10 shown in FIG. 3, which is manufactured by the method of the present embodiment, has a characteristic feature that the diameters of all the via conductors (the first via conductors 31 to the sixth via conductors 36) increase upward; that is, in the same direction.

In the present embodiment, in a method of manufacturing a so-called coreless multilayer wiring substrate in which a laminate structure including at least one conductor layer and at least one resin insulation layer is formed on a support substrate, a core substrate is also laminated together with the laminate structure, and an additional laminate structure having a configuration similar to that of the laminate structure is laminated on the core substrate. In the method of manufacturing the coreless multilayer wiring substrate, the support substrate is removed after formation of the laminate structure on the support substrate as mentioned above. Therefore, there finally remains a structure in which the core substrate is sandwiched by the laminate structures each including at least one conductor layer and at least one resin insulation layer; namely, a multilayer wiring substrate having a core substrate.

In the present embodiment, a method of manufacturing a coreless multilayer wiring substrate is utilized for manufacture of the multilayer wiring substrate 10 having the core substrate (the third resin insulation layer 23 and the metal layer 55). Therefore, in the manufacturing process, the first laminate structure 20A, the second laminate structure 20B, and the core substrate are formed on the support substrate S. Accordingly, even when the core substrate has a reduced thickness, the strength of an assembly formed in the manufacturing process is prevented from lowering by increasing the thickness of the support substrate S to a sufficient degree.

Accordingly, the assembly formed in the manufacturing process can be horizontally transported, and it becomes possible to avoid the occurrence of a problem that the assembly comes in contact with transport equipment during transportation, whereby the core substrate or the assembly is damaged. Also, it becomes possible to avoid the occurrence of a problem that, when the assembly is fixed and supplied to a predetermined manufacturing step, the assembly deforms, so that it becomes difficult to accurately carry out treatment such as plating treatment. For this reason, the multilayer wiring substrate 10 including a thin core substrate can be obtained with a high manufacturing yield, and thus the multilayer wiring substrate 10 having the core substrate can be miniaturized.

The method of the present embodiment is not limited to manufacture of a multilayer wiring substrate which includes a thin core substrate and which has such a structure that, if a common manufacturing method is used, due to the thin core substrate, the core substrate or an assembly formed in the manufacturing process deforms, which lowers manufacturing yield. The method of the present embodiment can be applied to the case where a multilayer wiring substrate includes a thick core substrate, and, even if a common manufacturing method is used, the multilayer wiring substrate including the thick core substrate can be manufactured with a high manufacturing yield.

In the present embodiment, when the fourth conductor layer 14 is formed, a so-called subtractive method is used to form the same. However, in place of such a subtractive method, a semi-additive method may be used to form the same.

### Second Embodiment

Multilayer Wiring Substrate

FIG. 17 is an enlarged partial sectional view of a multilayer wiring substrate according to a second embodiment, which corresponds to FIG. 3 associated with the first embodiment. In addition, in the drawings associated with the second embodiment, components similar to or identical with those of the multilayer wiring substrate 10 of the first embodiment are denoted by the same reference numerals.

A multilayer wiring substrate 10′ shown in FIG. 17 has the same structure as that of the multilayer wiring substrate 10 of the first embodiment except that a plating layer 23M is formed on the wall surface of each of through holes 23H formed in the third resin insulation layer 23 constituting the core substrate such that the plating layer 23M is connected to the fourth conductor layer 14 formed on the third resin insulation layer 23, and the through holes 23H are filled with a resin insulation layer 231. Such differences in structure are due to a manufacturing method described below.

Method of Manufacturing Multilayer Wiring Substrate

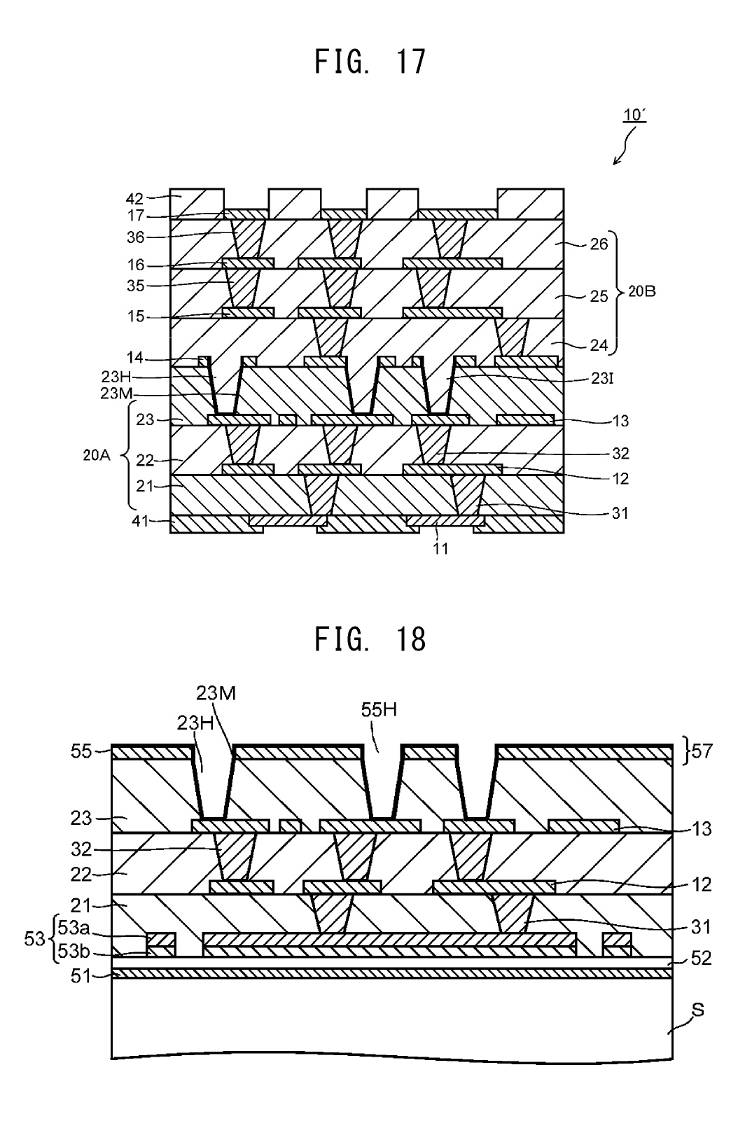

FIGS. 18 to 21 are sectional views showing the steps of the method of manufacturing the multilayer wiring substrate 10′ according to the second embodiment. Each of the views shown in FIGS. 18 to 21 corresponds to the sectional view of the multilayer wiring substrate 10′ shown in FIG. 17.

In actuality, the manufacturing method of the second invention is used to form the multilayer wiring substrate 10′ on each of the opposite sides of a support substrate; however, in the second embodiment, a case where the multilayer wiring substrate 10′ is formed only on one side of the support substrate will be described so as to clarify the features of the manufacturing method of the present invention.

Through the steps of the first embodiment shown in FIGS. 4 to 7, there is formed the first laminate structure 20A, which includes the first metal film 54a (which becomes the first conductor layer 11 later), the second and third conductor layers 12 and 13, the first and second resin insulation layers 21 and 22, and the first and second via conductors 31 and 32.

Then, as shown in FIG. 18, a prepreg layer 23X having a metal layer 55 formed on its upper main surface is laminated on the second resin insulation layer 22 such that the prepreg layer 23X covers the third conductor layer 13 and the lower main surface of the prepreg layer 23X comes in contact with the second resin insulation layer 22, followed by the hot pressing of the prepreg layer 23X under vacuum, whereby the prepreg layer 23X is pressure bonded to the second resin insulation layer 22 and is cured. Since the prepreg layer 23X includes reinforcing fibers such as fiberglass, the third resin insulation layer 23 obtained by curing the prepreg layer 23X through application of heat thereto constitutes a core substrate.

The above-mentioned vacuum hot pressing is carried out at a temperature equal to or higher than the glass transition point of the first resin insulation layer 21 and the second resin insulation layer 22. Therefore, when the core substrate composed of the metal layer 55 and the third resin insulation layer 23 is formed on the first laminate structure 20A, the first laminate structure 20A can be prevented from warping. As a result, it is possible to reduce warpage of at least a portion of the finally obtained multilayer wiring substrate 10′, which portion is located below the third resin insulation layer (the core substrate) 23. Accordingly, warpage of the entire multilayer wiring substrate 10′ can be reduced.

Next, as shown in FIG. 18, the metal layer 55 is partially etched and removed so as to form openings 55H, followed by irradiation of laser light to the third resin insulation layer 23 through the openings 55H so as to form through holes 23H such that the third conductor layer 13 is exposed. In this case, as in the step shown in FIG. 9, the openings 55H are previously formed in the metal layer 55 at positions where the through holes 23H are to be formed in the third resin insulation layer (the core substrate) 23. Therefore, the above-mentioned laser light impinges directly onto the third resin insulation layer 23 without passing through the metal layer 55.

Therefore, when the through holes 23H are formed using laser light in the third resin insulation layer 23 constituting the core substrate, a step of forming openings in the metal layer 55 using laser light can be omitted, and thus laser irradiation energy required for formation of the through holes 23H can be decreased, whereby the manufacturing cost of the multilayer wiring substrate 10′ can be lowered.

Subsequently, as shown in FIG. 18, desmearing and outline etching are properly applied to the through holes 23H, followed by so-called through-hole plating, whereby the plating layer 23M is formed on the wall surface of each through hole 23H such that the plating layer 23M is connected to the metal layer 55.

Notably, the plating layer 23M is also formed on the metal layer 55 as a result of performance of the above-mentioned through-hole plating. As mentioned above, the metal layer 55 can be formed of copper, and the plating layer 23M can be also formed of copper. Therefore, the plating layer 23M carries out the same function as the metal layer 55, and thus the plating layer 23M can form a single metal layer in cooperation with the metal layer 55.

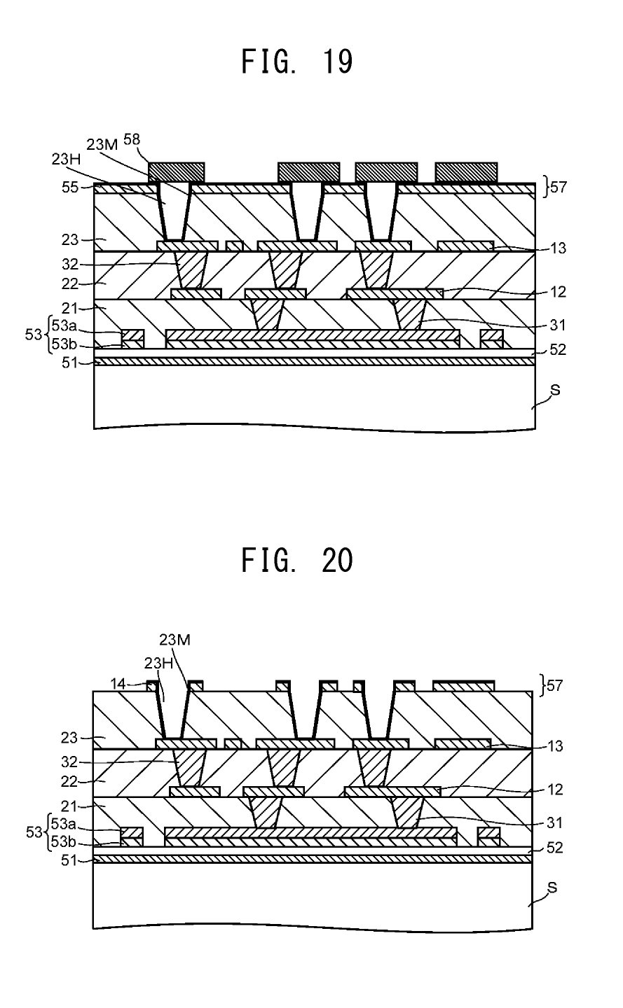

Subsequently, as shown in FIG. 19, a resist layer 58 of a predetermined pattern is formed on the metal layer 55 such that the resist layer 58 closes the through holes 23H, and then as shown in FIG. 20, the metal layer 55 is etched through openings of the resist layer 58, followed by the removal of the resist layer 58, whereby the fourth conductor layer 14 is formed on the third resin insulation layer 23.

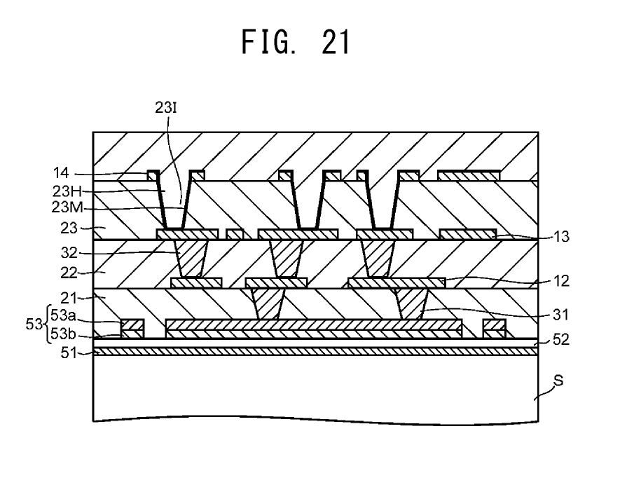

Next, after the fourth conductor layer 14 is roughened, as shown in FIG. 21, a resin film (a resin insulation material) is laminated on the third resin insulation layer 23 such that the resin film covers the fourth conductor layer 14 and fills the through openings 23H, followed by curing through application of pressure and heat to the resin film under vacuum, whereby the fourth resin insulation layer 24 is formed, and resin insulators 231 filling the through openings 23H are formed.

Subsequently, treatments similar to those preformed in the steps shown in FIGS. 14 to 16 are carried out so as to obtain the multilayer wiring substrate 10′ shown in FIG. 17.

The multilayer wiring substrate 10′ shown in FIG. 17, which is manufactured by the method of the second embodiment, has a characteristic feature that the diameters of all the via conductors (the first via conductors to the sixth via conductors) formed in the core substrate, and the diameters of the plating layers 23M on the wall surfaces of the through holes 23H increase upward, that is, in the same direction. In the case where copper foil is used for the metal layer 55, the fourth conductor layer 14 is constituted by two layers; i.e., the metal layer 55 and the plating layer 23M.

According to the second embodiment, in the steps as shown in FIGS. 18 to 21, the through holes 23H are formed in the core substrate, the plating layer 23M is formed on the wall surface of each of the through holes 23H, and the through holes 23H are filled with (or buried by) the resin insulators 231, which are formed through use of a resin sheet for forming the fourth resin insulation layer 24. In this case, it is possible to eliminate complicated steps in a conventional method of manufacturing a multilayer wiring substrate having a core substrate, such as a step of plating through holes of the core substrate, a step of burying the through holes by filling the through holes with resin, and a step of polishing the filling resin. That is, the manufacturing steps of the multilayer wiring substrate 10′ can be simplified.

In the second embodiment as well, in a method of manufacturing a so-called coreless multilayer wiring substrate in which a laminate structure including at least one conductor layer and at least one resin insulation layer is formed on a support substrate, a core substrate is also laminated together with the laminate structure, and an additional laminate structure having a configuration similar to that of the laminate structure is laminated on the core substrate. Therefore, after removal of the support substrate, there remains a structure in which the core substrate is sandwiched between the laminate structures each including at least one conductor layer and at least one resin insulation layer.

In the second embodiment, a method of manufacturing a coreless multilayer wiring substrate is utilized for manufacture of the multilayer wiring substrate 10′ having the core substrate (the third resin insulation layer 23 and the metal layer 55). Therefore, in the manufacturing process, the first laminate structure 20A, the second laminate structure 20B, and the core substrate are formed on the support substrate S. Accordingly, even when the core substrate has a reduced thickness, the strength of an assembly formed in the manufacturing process is prevented from lowering by increasing the thickness of the support substrate S to a sufficient degree.

Accordingly, the assembly formed in the manufacturing process can be horizontally transported, and it becomes possible to avoid the occurrence of a problem that the assembly comes in contact with transport equipment during transportation, whereby the core substrate or the assembly is damaged. Also, it becomes possible to avoid the occurrence of a problem that, when the assembly is fixed and supplied to a predetermined manufacturing step, the assembly deforms, so that it becomes difficult to accurately carry out treatment such as plating treatment. For this reason, the multilayer wiring substrate 10′ including a thin core substrate can be obtained with a high manufacturing yield, and thus the multilayer wiring substrate 10′ having the core substrate can be miniaturized.

The method of the second embodiment is not limited to manufacture of a multilayer wiring substrate which includes a thin core substrate and which has such a structure that, if a common manufacturing method is used, due to the thin core substrate, the core substrate or an assembly formed in the manufacturing process deforms, which lowers manufacturing yield. The method of the present embodiment can be applied to the case where a multilayer wiring substrate includes a thick core substrate, and, even if a common manufacturing method is used, the multilayer wiring substrate including the thick core substrate can be manufactured with a high manufacturing yield.

Embodiments of the present invention have been described in detail herein. However, the present invention is not limited to the embodiments, and any modification or change is possible without departing from the scope of the present invention.

In the embodiments mentioned above, there has been descried the manufacturing method of a multilayer wiring substrate in which the first resist layer 41 and the second resist layer 42 are formed to obtain the multilayer wiring substrate 10, 10′ after removal of the support substrate S. However, when the number of layers is to be increased, the manufacturing method may include a step which is performed, after removal of the support substrate S, so as to laminate an additional conductor layer(s) and an additional resin insulation layer(s) on each of the first laminate structure 20A and the second laminate structure 20B.

In the embodiments mentioned above, there has been descried the manufacturing method of the multilayer wiring substrate, in which conductor layers and resin insulation layers are successively laminated from the side of the conductor layer which forms back side lands for connection with a mother board toward the side of the conductor layer which forms pads (FC pads) to which a semiconductor or the like is connected through flip chip connector. However, no particular limitation is imposed on the sequence of the lamination, and conductor layers and resin insulation layers may be laminated from the side of the conductor layer which forms the FC pads toward the side of the conductor layer which forms the back side lands.

### DESCRIPTION OF REFERENCE NUMERALS

10, 10′: multilayer wiring substrate
11: first conductor layer
12: second conductor layer
13: third conductor layer
14: fourth conductor layer
15: fifth conductor layer
16: sixth conductor layer
17: seventh conductor layer
21: first resin insulation layer
22: second resin insulation layer
23: third resin insulation layer
24: fourth resin insulation layer
25: fifth resin insulation layer
26: sixth resin insulation layer
31: first via conductor
32: second via conductor
33: third via conductor
34: fourth via conductor
35: fifth via conductor
36: sixth via conductor
41: first resist layer
42: second resist layer

What is claimed is:

1. A method of manufacturing a multilayer wiring substrate, comprising:
a first laminate structure formation step of forming a first laminate structure on a support substrate, the first laminate structure including at least one conductor layer and at least one resin insulation layer;
a core substrate formation step of laminating a core substrate on the first laminate structure such that a lower main surface of the core substrate comes in contact with the first laminate structure, the core substrate having a metal layer provided on an upper main surface thereof; and
a second laminate structure formation step of forming a second laminate structure on the core substrate, the second laminate structure including at least one conductor layer and at least one resin insulation layer.

2. The method of manufacturing a multilayer wiring substrate according to claim 1, wherein the core substrate formation step includes:
forming a through hole in the core substrate laminated on the first laminate structure; and
filling the through hole with plating.

3. The method of manufacturing a multilayer wiring substrate according to claim 1, wherein the core substrate formation step includes:
forming a through hole in the core substrate laminated on the first laminate structure;
forming a plating layer on a wall surface of the through hole; and
forming with a resin insulating material the resin insulation layer of the second laminate structure and an insulator which fills the through hole.

4. The method of manufacturing a multilayer wiring substrate according to claim 2, wherein:
the core substrate formation step includes removing the metal layer at a location where the through hole is to be formed in the core substrate; and
the through hole is formed through irradiation of laser light.

5. The method of manufacturing a multilayer wiring substrate according to claim 3, wherein:
the core substrate formation step includes removing the metal layer at a location where the through hole is to be formed in the core substrate; and
the through hole is formed through irradiation of laser light.

6. The method of manufacturing a multilayer wiring substrate according to claim 1, wherein the core substrate formation step includes laminating the core substrate on the first laminate structure by pressure-bonding the core substrate to the first laminate structure at a temperature equal to or higher than a glass transition point of the resin insulation layer of the first laminate structure.
